(19) United States
(12) Patent Application Publication
(10) Pub. No.: US 2012/0267243 A1
(43) Pub. Date: Oct. 25, 2012

(54) SYSTEMS AND METHODS FOR A TARGET AND BACKING PLATE ASSEMBLY

(75) Inventor: Eugene Y. Ivanov, Grove City, OH (US)

(73) Assignee: TOSOH SMD, INC., Grove City, OH (US)

(21) Appl. No.: 13/541,327

(22) Filed: Jul. 3, 2012

Related U.S. Application Data
(63) Continuation of application No. 12/586,319, filed on Sep. 21, 2009.
Application No. 12/586,319 is a continuation of application No. 10/526,704, filed on Jul. 19, 2005, now abandoned.
(60) Provisional application No. 60/454,442, filed on Mar. 13, 2003.
(60) Provisional application No. 60/411,917, filed on Sep. 19, 2002.
(60) Provisional application No. 60/410,606, filed on Sep. 13, 2002.

(51) Int. Cl. B23K 20/22; B23K 20/24; C23C 14/34

(52) U.S. Cl. 204/298.13; 204/298.12; 228/193; 228/174

(57) ABSTRACT

A target and backing plate assembly and method of making the same. The target and backing plate assembly provides a mechanical interlock between the target and backing plate in addition to diffusion bonding between dissimilar materials comprising the target and backing plate. An interlayer may also be used between the target and backing plate. A plurality of ridges, or other salient surface features on one of the target and backing plate are joined to corresponding members or channels on the other of the target and backing plate. The dissimilar materials of the target and backing plate fill negative angled cavities formed by the plurality of ridges and corresponding channels or members of the target and backing plate to accommodate the diffusion bonded dissimilar materials. A target and backing plate assembly with increased strength results.

### CROSS-REFERENCE TO RELATED APPLICATIONS

The present application is a continuation of U.S. patent application Ser. No. 12/586,319 filed Sep. 21, 2009 which is a continuation of U.S. patent application Ser. No. 10/526,704 filed Jul. 19, 2005 which was a national phase filing under 35 USC §371(c) of PCT International Application Serial No. PCT/US2003/026465 having an international filing date of Aug. 26, 2003. The PCT application, in turn, claimed benefit of prior U.S. Provisional Application No. 60/410,606 filed Sep. 13, 2002, U.S. Provisional Application No. 60/411,917 filed Sep. 19, 2002, and U.S. Provisional Application No. 60/454,442 filed Mar. 13, 2003.

### BACKGROUND OF THE INVENTION

1. Field of Invention

This invention relates to a sputter target/backing plate joining technique and assemblies made thereby.

2. Description of Related Art

Targets and backing plates are known wherein one of the joining, interfacial surfaces is machined, or otherwise formed, to have a plurality of ridges or other salient target surface portions. The ridges or other salient target surface portions are formed along a mating surface of the target or backing plate. The ridged surface is then placed along a corresponding mating surface of the other of the target or backing plate. Joining of the target and backing plate is then achieved under the influence of selected pressures and temperatures. For example, HIP or hot pressing techniques may be used to achieve the desired joining of the target to the backing plate. In some cases, an intermediate layer is used to improve bonding strength.

The use of increasing operating powers in present day sputtering systems has led to increased target/backing plate delamination. Accordingly, a need exists for a target and backing plate assembly that has increased bond strength so as to inhibit target/backing plate separation.

### SUMMARY OF THE INVENTION

This invention provides a target and backing plate of dissimilar mechanical properties, wherein one of the target and backing plate is machined, or otherwise formed, to have a plurality of ridges and grooves, or other salient surface portions to form a mating surface having negative angled cavities into which diffusion bonding of one material with the other material may occur. As a result, a mechanical interlock having increased bonding strength occurs between the target and the backing plate. In addition, diffusion bonding of the material forming the target with the material forming the backing plate also occurs. The combination of the mechanical interlock with the diffusion bonding of the dissimilar materials of the target and backing plate provides a target and backing plate assembly with increased strength.

The mating surface is thus placed alongside a corresponding mating surface of the other of the target and backing plate to form an interface between the target and backing plate. The target and backing plate are then joined applying high pressure and selected temperature conditions appropriate to the materials used to form the target and backing plate.

The projection of the plurality of ridges formed along the one of the target and backing plate penetrate into corresponding grooves, or mating members, on the other of the target and backing plate to permit the diffusion bonding of the opposed mating surface materials to occur at the interface between the target and backing plate.

In one aspect of the invention, “dove-tail” or tenon-like projections are provided in place of, or in addition to, the plurality of ridges on the mating surface of one of the target and backing plate. The dove-tail portions provide a mechanical interlock with corresponding receiving channels on the other of the target and backing plate. The dove-tail portions may be located either at the outside perimeter of the target or backing plate, with corresponding receiving members on the other of the target or backing plate. Alternatively, multiple dove-tail portions may be provided interior of the outside diameter of the target or backing plate with corresponding receiving channels on the other of the target and backing plate. The combination of the dove-tail portions and the corresponding receiving channels provides a mechanical interlock at each combination thereof, and the negative angled cavities formed by the interface of the dove-tailed portions and receiving channels permit diffusion bonding of dissimilar target and backing plate materials.

In another aspect of the invention the dove-tail portions are generally trapezoidally shaped. A calculated mismatch in the height of one dove-tail portion versus another dove-tail portion is provided to achieve mechanical interlocks at various positions along the interface of the target and the backing plate. The varying positions of the mechanical interlocks also permit diffusion bonding to occur at various depths along the interface of the target and backing plate according to the negative angles created by the different height dimensions of the dove-tail portions.

In various exemplary embodiments of the systems and methods of the invention, the target and backing plate are pressed together such that the plurality of ridges, or other salient portions, such as the dove-tail portions, are pressed together to form an assembly. The softer material of the target and backing plate will flow into the negative angled cavities formed by the plurality of ridges, or other salient portions, such as the dove-tail portions such that a mechanical joint is formed between the target and backing plate and diffusion bonding of the two materials of the target and backing plate occurs as well. After pressing the target and backing plate together, a final machining of the exposed surfaces of the target and backing plate is performed to provide the exposed surfaces with a finish as desired.

In still other exemplary embodiments of the invention, an interlayer may be placed between the target and backing plate prior to joining the target and backing plate together. The interlayer may comprise a material that is dissimilar from either of the target and the backing plate. Once the interlayer is in place, the process of joining the target and backing plate is essentially the same as that described above to yield a target, interlayer and backing plate assembly with increased mechanical and diffusion bonding strength.

These and other features and advantages of this invention are described in, or are apparent from, the following detailed description of various exemplary embodiments of the systems and methods according to this invention.

### BRIEF DESCRIPTION OF THE DRAWINGS

Various exemplary embodiments of the systems and methods of this invention will be described in detail with reference to the following figures, wherein:

FIG. 1 illustrates one exemplary embodiment of a target and backing plate in accordance with the invention, prior to assembly;

FIG. 2 illustrates an assembled view of the target and backing plate of FIG. 1;

FIG. 3 illustrates another exemplary embodiment of a target and backing plate assembly according to the invention;

FIG. 4 illustrates an exemplary view of a typical diffusion bond cross section of the target and backing plate assembly shown in FIG. 3;

FIG. 5 illustrates another exemplary embodiment of the target and backing plate assembly including an interlayer according to the invention; and

FIG. 6 illustrates an assembled view of the target and backing plate with interlayer of FIG. 5.

### DETAILED DESCRIPTION OF EXEMPLARY EMBODIMENTS

FIG. 1 shows an exemplary target 1 and backing plate 10. The target 1 includes a plural or bi-level mating surface 2 comprised of dove-tail portions 3 and 4, as shown in FIG. 1. Of course, the various levels of the mating surface 2 could instead be comprised of a plurality of grooves or other salient surface portions. In FIG. 1, the heights h1 and h2 of the dove-tail portions 3 and 4, respectively, differ by an amount x such that one dove-tail portion 4, for example, projects slightly further from the top target surface or sputtering surface and toward the backing plate 10. When the target 1 is comprised of such dove-tailed portions 3 and 4, the general shape of each dove-tailed portion may be trapezoidal, as seen in FIG. 1.

The backing plate 10 of FIG. 1 includes a bi-level mating surface 12 opposed to the bi-level mating surface 2 of the target 1. The mating surface 12 of the backing plate 10 includes receiving channels 13 and 14 having depths d1 and d2, respectively, that correspond roughly to the heights h1 and h2, respectively, of dove-tail portions 3 and 4 of the target 1. Of course, where the target 1 is provided with a plurality of ridges, or other salient surface portions other than the dove-tailed portions 3 and 4 shown in FIG. 1, the plural level mating surface 12 of the backing plate may be made congruent therewith.

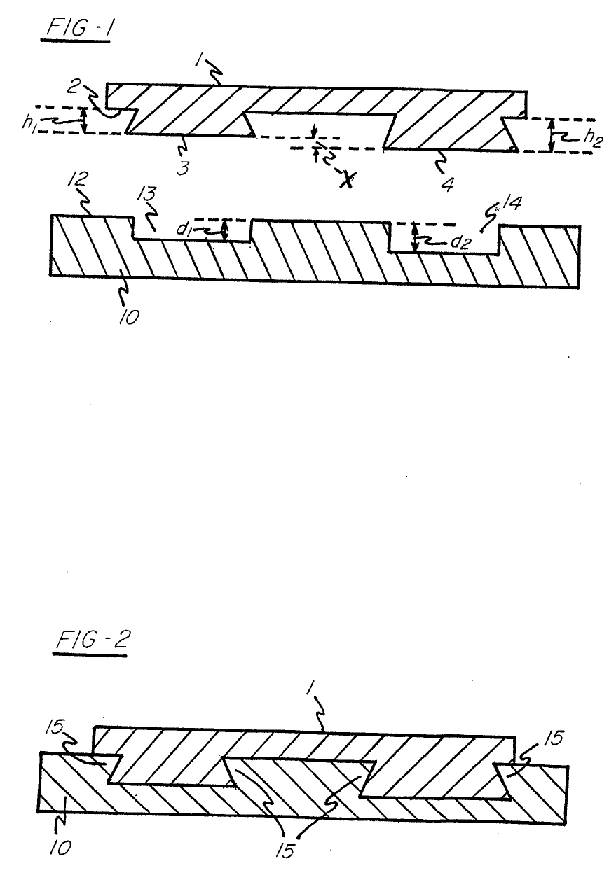

FIG. 2 shows the exemplary target 1 and backing plate 10 of FIG. 1 as a joined assembly. The penetration of the plurality of ridges, or other salient surface portions, such as the dove-tailed portions 3 and 4 of the target 1, for example, with the corresponding mating surface of the backing plate 10 achieve a mechanical interlock at the interface between the target 1 and backing plate 10. The mechanical interlock is rendered more stable, and less susceptible to undesirable separation, as a result of the different levels of contact between the bi-level mating surfaces 2 and 12 at the interface.

Ideally, the materials comprising the target 1 and the backing plate 10 have dissimilar mechanical properties, and thus are different materials. The target 1 may comprise Ta, for example, whereas the backing plate 10 may comprise Cu or a Cu alloy. It should be appreciated that other dissimilar materials may be used to comprise the target 1 and backing plate 10. Preferably, one of the materials will be softer than the other material. As a result, when pressing of the target 1 and backing plate 10 occurs at selected temperatures and high pressure, the softer material will fill negative or re-entrant angled cavities 15 (FIG. 2) formed by the dove-tailed portions 3 and 4, for example. Of course, where a plurality of ridges, or other salient surface portions are used instead of the dove-tailed portions 3 and 4, the softer material would fill any cavities formed by those ridges, or the like, and the receiving channels 13 and 14 when the target 1 and backing plate 10 are joined together under selected temperatures and high pressure.

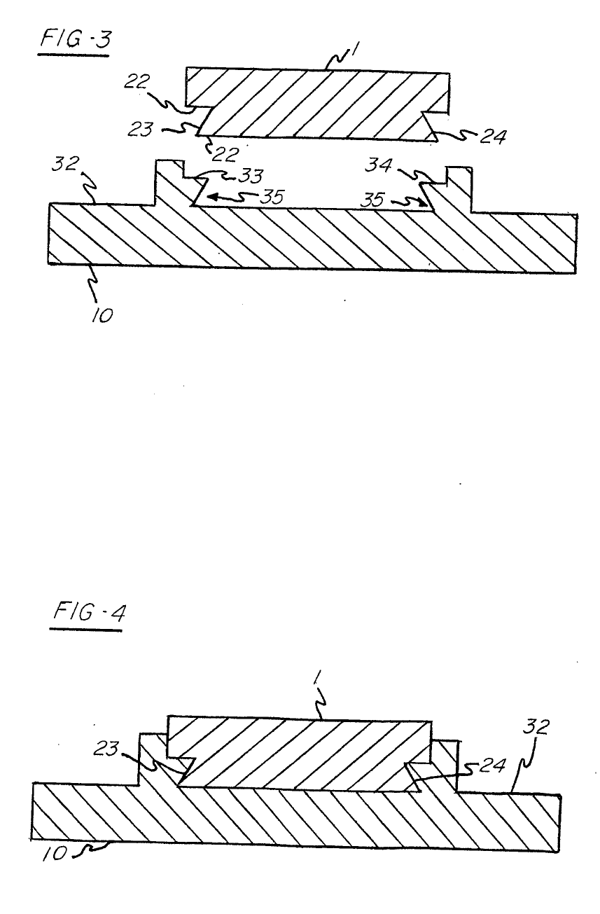

FIGS. 3 and 4 show another exemplary embodiment of the target 1 and backing plate 10 assembly according to the invention. Rather than having the bi-level dove-tailed portions 3 and 4 of differing heights h1 and h2 spaced apart from one another along the interior of the mating surface 2 of the target 1, as in the exemplary embodiment of FIG. 1, the target 1 of FIGS. 3 and 4 instead provides a plural level mating surface 22 having dove-tailed portions 23 and 24 positioned near, or at, an outer perimeter of the mating surface 22. The backing plate 10 of FIGS. 3 and 4 thus provides a plural level mating surface 32 having receiving members 33 and 34 that correspond to the plural mating surface 22 and dove-tailed portions 23 and 24 of the target 1. Negative angled cavities 35 are formed when the mating surfaces 22 and 32 of the target 1 and backing plate 10 are joined.

As a result of the corresponding target 1 and backing plate 10 of the exemplary embodiment shown in FIG. 3, the target 1 is mechanically interlocked with the backing plate 10 by joining the mating surfaces 22 and 32 under selected temperatures and high pressure as described above with reference to the first exemplary embodiment. In this embodiment however, the interlock occurs proximate the outer perimeter of the target 1. The interlock near, or at, the outer perimeter of the target 1 and backing plate 10 provides increased strength to the assembly at the perimeter, where separation is most likely to occur first.

As in the first exemplary embodiment, the target 1 and backing plate 10 of FIGS. 3 and 4 are formed of dissimilar materials, wherein one of the materials is softer than the other. As a result, the target 1 and backing plate assembly 10 are securely joined by the mechanical interlock of the dove-tailed portions 23 and 24 of the target 1 interfacing with the corresponding receiving members 33 and 34 of the backing plate 10. In addition, diffusion bonding of the dissimilar materials fills in the negative angled cavities 35 formed by the interface of the dove-tailed portions 23 and 24 with the receiving members 33 and 34 or other portions of the mating surfaces 22 and 32. Of course, where a plurality of ridges, or other salient surface portions are used instead of the dove-tailed portions 23 and 24, the softer material would fill any cavities formed by those ridges, or the like, and the receiving members 33 and 34 when the target 1 and backing plate 10 are joined together under selected temperatures and high pressure. As before, once the target 1 and backing plate 10 are joined, the exposed surfaces of the assembly may be machined to a desired finish.

### Example 1

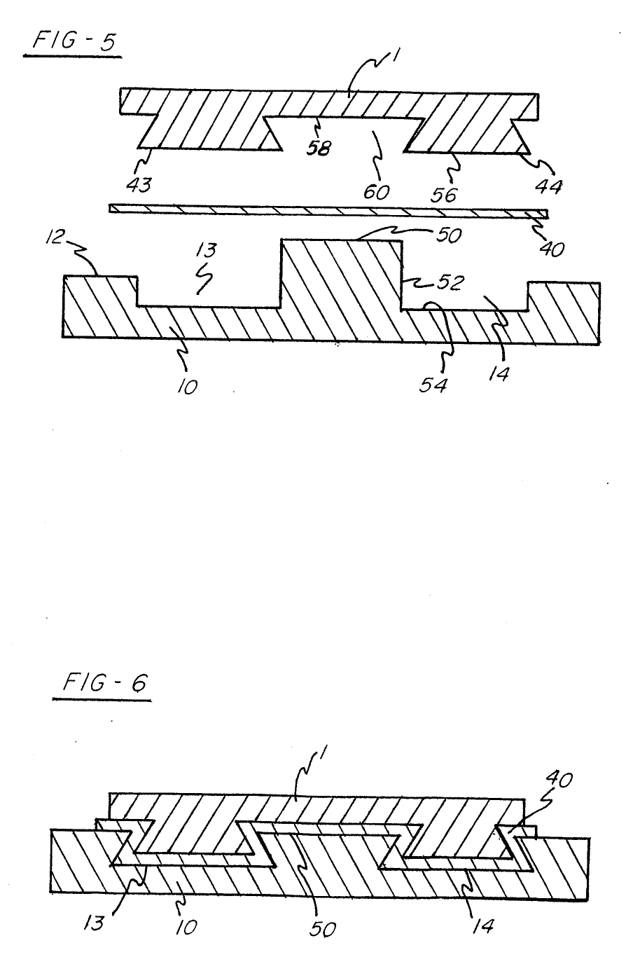

The shape of the mating members can be simple trapezoids in shape with a calculated mismatch in height as shown in FIGS. 5 and 6 (without interlayer). This arrangement was tried for Ta target/Cu—Zn backing plates and Ti target/Al 6061 backing plate assemblies. (See FIG. 5 assembly before HIP).

### Example 2

The Ta/Cu—Zn assembly before and after diffusion bonding HIP is seen in FIGS. 5 and respectively (without an interlayer). Two parts were pressed together so that projections and grooves were pressure consolidated against each other. The softer material, such as Cu—Zn alloy flows into the cavities with a negative angle forming a mechanical joint. After pressing, final machining was performed. The partition force required to separate a 12″ diameter Ta target from a Cu—Zn backing plate was estimated as 96,000 lbs.

### Example 3

The diffusion bond (DB) strength of a Ta target/CuZn backing plate assembly was measured using 1.996″ diameter standard assembly samples. The average of eight measurements resulted in a bond strength of 12,112 psi. The assembly was consolidated under HIP conditions of 700° C., 15 Kpsi, for three hours. The strength of the locking mechanism, measured at 3.00″ diameter Ta/CuZn sample of the FIG. 3 and FIG. 4 configurations required an average force of 30,000 lbs. to separate the target from backing plate.

FIGS. 5 and 6 illustrate yet another exemplary embodiment of the target 1 and backing plate 10 assembly according to the invention. As shown, prior to joining the target 1 and backing plate 10 together, an interlayer 40 is interposed between the target 1 and backing plate 10. FIG. 5 shows the interlayer 40 prior to joining of the target 1 to the backing plate 10. In this manner, the interlayer 40, upon joining of the assembly, conforms to the shape of the target 1 and the plurality of ridges, or other salient surface portions, such as dove-tailed portions 43 and 44, for example. The target 1 and interlayer 40 are thus joined to the backing plate 10 by insertion of the dove-tailed portions 43 and 44 of the target/interlayer 40 combination into corresponding receiving channels 13 and 14 in the backing plate 10 as described with reference to FIG. 1, for example. The assembly is preferably HIPed in accordance with the conditions set forth under Ex. 3 above to effect diffusion bonding of the assembly.

The interlayer 40 comprises, for example, Ag—Cu—Ni—Zn, or similar alloy such as Ag—Cu—Sn and is applied via HIP or hot pressing. The interlayer 40 is ideally a material different from either of the target 1 material or the backing plate 10 material. In this manner, when the selected temperature and high pressure is applied to join the interlayer 40 in its position intermediate the target 1 and the backing plate, the dissimilar materials will diffusively bond to each other to form a bond of increased strength. Less preferably components for the interlayer 40 comprise Ti, Ti/Al, Ni, NiV, and the like.

The interlayer 40 could be used with either of the embodiments described above to form an assembly of increased mechanical and diffusion bond strength. Thereafter, the exposed surfaces of the target 1 and backing plate 10 are machined to a desired finish, as before.

Turning back to FIGS. 5 and 6, in the embodiment shown therein, the softer metal, herein the backing plate 10 is provided with a central post 50 extending upwardly from the backing plate away from the channels 13, 14. The height of the post 50 as measured along wall 52 perpendicular to bottom surface 54 of the channel 14 is greater than the depth of the corresponding concavity 60 of the target. (The depth of the concavity is measured by a vector perpendicular to the top surface 58 of the concavity.) In this way, when the target, backing plate and interlayer are pressure consolidated via hipping, the softer material located in the elongated post is thrust radially outwardly filling the reentrantly angled walls of the concavity that circumscribe the surface 58.

In the embodiment shown in FIGS. 5 and 6, the depth of each of the channels 13, 14 is approximately equal and the heights or extension (vertical extension as shown in the drawings) of the dove tailed portions 43, 44 are also equal to each other. In this embodiment, a plural level mating surface is provided with one level represented by the bonding occurring proximate surface 58 and the other (i.e., lower in the drawing) level represented by the plane extending along bottom surfaces of the channels 13, 14.

The structural combination shown in FIGS. 5 and 6, with or without the interlayer is preferred. Preferred target/backing plate combinations are

| Target 1 | Backing Plate 10 |
|---|---|
| Ta | Cu/Zn |
| Ta | Cu/Cr |
| Ti | Cu/Zn |

The invention therefore deals with a diffusion bonded target/backing plate structure having plural interfacial mating levels or surfaces. For instance, in the embodiment depicted in FIG. 1, at least three mating heights or levels would be provided. More specifically, a first level would be provided along the plane represented by the bottom surface of channel 13 and a second plane would be defined by the bottom surface of channel 14. A third plane would be defined by the top most surface in the central concavity shown in the target 1. These first, second, and third planes are parallel to one another. In the embodiment shown in FIGS. 5 and 6, a first level or plane is represented by the interface taken along the surface 58 formed in the concavity 60 of target 1 with a second plane defined by the lower surfaces of the channel members 13 and 14. The first and second planes are parallel to each other.

In all of the various exemplary embodiments described herein, the target 1 material may be chosen from the group consisting of non-magnetic materials such as Al, Cu, Ti, Al—Ti, NiV, Ag, Sn, Au, Ta, Co, and Ni, for example, and the backing plate 10 materials may comprise, for example, Al, Ti, Cu, or the like. (Alloys of all metals are included.) In either case, one of the materials must be ductile during selected temperature pressing so that the negative angle cavities form mechanical interlocks together with diffusion bonding to achieve the desired bonding strength of the target and backing plate assembly.

While this invention has been described in conjunction with the specific embodiments above, it is evident that many alternatives, combinations, modifications, and variations are apparent to those skilled in the art. Accordingly, the preferred embodiments of this invention, as set forth above, are intended to be illustrative, and not limiting. Various changes can be made without departing from the spirit and scope of this invention.

What is claimed is:

1. A target and backing plate assembly, each of said target and backing plate including a mating surface adapted to mate with the other along an interfacial surface, said target and said backing plate mating along a plurality of differing depth level locations of said interfacial surface, each of said depth level locations including at least one protruding member and at least two receiving channels formed in one of said target and backing plate and a negatively angled cavity formed in the other of said target and backing plate, said target and backing plate being composed of metals having different hardnesses whereby one of said target and backing plate is softer than the other, each of said depth level locations including a diffusion bond formed between interfacial surfaces of said target and backing plate located thereat, said assembly further comprising a mechanical interlock at each said depth level location defined by filling of said softer metal in said negatively angled cavity, wherein at least one protruding member defines a post extending upwardly from one of target and said backing plate and away from said receiving channels; and
wherein a wall height of said post as measured perpendicular from a bottom surface of said receiving channels is greater than a cavity depth of said corresponding negatively angled cavity, said cavity depth measured by a vector perpendicular to a top surface of said negatively angled cavity.

2. The assembly of claim 1, wherein an interlayer is positioned between the target and backing plate.

3. The assembly of claim 2, wherein the interlayer is comprised of a third material different than the target and backing plate metals.

4. The assembly of claim 1 wherein said target comprises Ta and wherein said backing plate comprises Cu.

5. The assembly as recited in claim 4 wherein said backing plate comprises CuZn alloy.

6. The assembly as recited in claim 4 wherein said backing plate comprises Cu Cr.

7. The assembly as recited in claim 4 wherein the average partition force needed to separate said Ta target from said Cu or Cu alloy backing plate is 30,000 lbs.

8. A method of forming a target and backing plate assembly, said method comprising:
providing a target and a backing plate, said target and said backing plate being composed of different metals, said metals each having a hardness that is different from the other metal whereby one of said target and backing plate is softer than the other;
positioning said target and backing plate adjacent each other so that they mate along an interfacial area;
providing a plurality of differing depth level locations within said interfacial area along which said target and backing plate mate;
providing at least one protruding member and at least two receiving channels on one of said target and backing plate and a negatively angled cavity in the other of said target and backing plate at each of said depth level locations, wherein at least one protruding member defines a post extending upwardly from one of target and said backing plate and away from said receiving channels and wherein a wall height of said post as measured perpendicular from a bottom surface of said receiving channels is greater than a cavity depth of said corresponding negatively angled cavity, said cavity depth measured by a vector perpendicular to a top surface of said negatively angled cavity;
pressure consolidating said target and backing plate under selected pressure and temperature conditions to form a diffusion bond between said target and said backing plate at each of said depth level locations while forming a mechanical interlock at each of said depth level locations defined by filling of the softer of said target or backing plate in said negatively angled cavities.

9. The method as recited in claim 8 wherein said target comprises Ta and said backing plate comprises Cu.

10. The method as recited in claim 9 wherein said backing plate comprises Cu/Cr.

11. The method as recited in claim 9 wherein said backing plate comprises Cu/Zn.

12. The assembly of claim 1 wherein protrusions on said target define peripheral dovetails on said target thereby forming a central dovetail trapezoid on said target, said dovetail trapezoid defining said negatively angled cavity.

13. The assembly of claim 12 wherein said receiving channels are located on said backing plate and wherein said receiving channels correspond to said peripheral dovetails on said target.

14. The assembly of claim 13 wherein said post is located on said backing plate and said post corresponds to said dovetail trapezoid on said target wherein said post has a height greater than a depth of said dovetail trapezoid.

15. The assembly of claim 14 wherein said receiving channels on said backing plate have approximately equal depths.

16. The method of claim 8 wherein protrusions on said target define peripheral dovetails on said target thereby forming a central dovetail trapezoid on said target, said dovetail trapezoid defining said negatively angled cavity.

17. The method of claim 16 wherein said receiving channels are located on said backing plate and wherein said receiving channels correspond to said peripheral dovetails on said target.

18. The method of claim 17 wherein said post is located on said packing plate and said post corresponds to said dovetail trapezoid on said target wherein said post has a height greater than a depth of said dovetail trapezoid.

19. The method of claim 18 wherein said receiving channels on said backing plate have approximately equal depths.
